(19) United States
(12) Patent Application Publication
(10) Pub. No.: US 2003/0129305 A1
(43) Pub. Date: Jul. 10, 2003

(54) Two-dimensional nano-sized structures and apparatus and methods for their preparation

(76) Inventors: Yihong Wu, Singapore (SG); Tow Chong Chong, Singapore (SG)

Correspondence Address: MARTINE & PENILLA, LLP, 710 LAKEWAY DRIVE, SUITE 170, SUNNYVALE, CA, 94085, US

(21) Appl. No.: 10/124,188

(22) Filed: Apr. 16, 2002

(30) Foreign Application Priority Data
Jan. 8, 2002 (SG) 200200085-9

(51) Int. Cl. C23C 16/00

(52) U.S. Cl. 427/255.28; 118/723 R; 118/723 E; 118/723 MW

(57) ABSTRACT

The invention concerns two-dimensional, nano-sized structures, formed of e.g. carbon, boron nitride, SiC, MoS₃, MoSe₂, GaN, ZnO, TiO₂ and mixtures thereof, and apparatus and methods for their preparation.

This invention is concerned with substantially planar or plate-like, nano-sized structures, such as planar graphene sheets and nanowalls of other materials, and apparatus and methods for their preparation.

Natural and synthetic graphite comprises many layers of hexagonal, plate-like crystals held together by very weak bonding forces. The plate-like, crystalline layers are singularly referred to as graphene sheets. In graphite, the graphene sheets are substantially planar.

Fullerenes and carbon nanotubes are examples of synthetic, nano-sized structures of carbon. The term “nano-sized” is used herein to indicate that the structure comprises at least one dimension that is no greater than 100 nm. Fullerenes are considered to be nano-sized, zero-dimensional forms of carbon. The term “zero-dimensional” is used herein to indicate that the structure has nanometer scale dimensions in all directions. Carbon nanotubes are considered to be nano-sized forms of carbon exhibiting a quasi-one-dimensional structure. The term “one-dimensional” is used herein to indicate that the structure has only one dimension greater than 100 nm. A carbon nanotube may be formed of a substantially non-planar graphene sheet i.e. the nanotube appears, in effect, as if it is formed from a graphene sheet that has been rolled into itself.

Fullerenes and carbon nanotubes demonstrate unique mechanical, chemical, and electronic properties, which have been exploited in a number of applications, such as in the manufacture of electronic devices, energy storage devices, field emission devices, catalysts and absorption media. It is believed that substantially planar graphene sheets and nanowalls of other materials may provide unique mechanical, chemical or electronic properties that may also have potentially advantageous applications.

It is an object of the present invention to provide a method for the preparation of two-dimensional nano-sized structures, such as graphene sheets, which are substantially planar or plate-like in appearance. It is another object of the present invention to provide apparatus suitable for use in the manufacture of such two-dimensional nano-sized structures. It is yet another object of this invention to provide new, substantially planar nano-sized structures that are other than graphene sheets.

In accordance with a first aspect of the present invention, there is provided a process for the preparation of a two-dimensional, nano-sized structure by chemical vapour deposition (CVD) process, the process comprising directing a stream of building material on to a first surface of a target plate for an appropriate period of time to enable a nano-sized structure of said building material to develop on said surface; wherein said target plate comprises said first surface and a second surface on the opposite side of said target plate; characterized in that said first surface of said target plate is electrically insulated from said second surface of said target plate. Preferably, the two-dimensional nano-sized structure is prepared by a microwave plasma enhanced chemical vapour deposition (MPECVD) process, wherein a stream of plasmatized building material is directed on to said first surface. The two-dimensional, nano-sized structure may be prepared by other CVD processes, such as by thermal CVD, wherein a stream of reaction gas is directed on to said first surface.

In one particular embodiment of the first aspect of the present invention, the process comprises directing a stream of building material on to a first surface of a target plate for an appropriate period of time to enable a nano-sized structure of said building material to develop on said surface; wherein said target plate comprises said first surface and a second surface on the opposite side of said target plate; wherein said target plate is located between a first electrode and a second electrode of a pair electrodes, preferably a pair of parallel plate electrodes, with said first surface facing but separated from said first electrode, wherein said pair of electrodes are connected to means, e.g. a direct current power supply means, a pulsed direct current power supply means, or an RF power supply means, that provides an electric field between said electrodes with a zero (earth) or positive charge on said first electrode and a negative charge on said second electrode, characterized in that said first surface of said target plate is electrically insulated from said second electrode.

The key for the growth of nano-sized two-dimensional structures is believed to lie in the establishment of a two-dimensional electric field in close proximity to the place where the growth is required i.e. in the region immediately above the first surface of the target plate. For example, in the above-preferred embodiment, an electric field is established on or immediately above the first surface of the target plate by placing the target plate between two parallel plate electrodes. However, a person skilled in the art will recognise that there are other ways and means for establishing an electric filed on or immediately above the first surface of the target plate. For example, a localized electric filed may be formed by using just the plasma itself, without the use of an external bias. It is well-known that the plasma will induce an electric field in the shield region. Furthermore, the electric field may also be set up via surface plasmon effect.

The process of the present invention enables nanowalls of building material to be formed on the first surface of the target plate. The nanowalls are substantially planar. Generally, the nanowalls are oriented perpendicular to the plate surface.

The nanowalls formed by the process of the present invention tend to be formed uniformly over the first surface of the target plate. Selective growth of nanowalls may be achieved through patterning the target plate surface.

By varying the electrical conductivity of the target plate during the process, (making the first surface electrically insulated from the second electrode and then changing it to be electrically connected to the second electrode, and visa versa) it may be possible to grow a mixture of both nanotubes and nanowalls on the first surface of the target plate.

In accordance with another aspect of the present invention, there is provided a two-dimensional nano-sized structure that is other than a graphene sheet. Such a structure is obtainable by above process. Preferably, the structure is obtained by the above process.

In accordance with another aspect of the present invention, there is provided chemical vapour deposition (CVD) apparatus suitable for the preparation of two-dimensional nano-sized structures comprising a) a growth chamber comprising a target plate having a first surface suitable for receiving a stream of building material and a second surface on the opposite side of said target plate; and b) means for establishing an electric field on or immediately above said first surface of said target plate; characterized in that said first surface of said target plate is electrically insulated from said second electrode.

In a particular embodiment of this aspect of the present invention, said CVD apparatus comprises a) a growth chamber comprising a target plate having a first surface suitable for receiving a stream of building material and a second surface on the opposite side of said target plate; wherein said target plate is located between a first electrode and a second electrode of a pair electrodes, preferably a pair of parallel plate electrodes, with said first surface facing but separated from said first electrode, and b) means for providing an electric field between said electrodes with a zero (earth) or positive charge on said first electrode and a negative charge on said second electrode; characterized in that said first surface of said target plate is electrically insulated from said second electrode.

Preferably, the apparatus is microwave plasma enhanced chemical vapour deposition (MPECVD) apparatus, wherein a stream of plasmatized building material is received on to said first surface. (MPECVD apparatus typically comprises a microwave generator, a vacuum chamber with gas inlets and pumping outlets, a pair of electrodes, and a DC power supply to provide bias to the electrodes). Other CVD apparatus may also be used, such as thermal CVD apparatus.

It is believed that any material that may be deposited by conventional CVD will be suitable for use as a building material in the present invention. The building material is preferably selected from carbon, boron nitride, SiC, MoS₃, MoSe₂, GaN, ZnO, TiO₂ and mixtures thereof. The two-dimensional, nano-sized structures formed from such building materials will thus also be comprised of such material.

The building material may be introduced into the stream from a reaction gas. It is believed that any gas that may be used in conventional CVD will be suitable for use as a reaction gas in the present invention. The reaction gas preferably comprises one or more of the following C₂H₄, CO₂, SiH₄, H₂S, H₂Se, trimethyl gallium, diethyl zinc, TiCl₄, O₂, N₂, Ar, H₂ and NH₃. The formation of the nanowalls may be controlled by adjusting the rate and direction of gas flow.

A collimated ion beam, e.g. consisting of C atoms, may be used as the source of building material. In this embodiment, the energy of the ions may be varied using standard ion beam control techniques.

The process of the present invention may be conducted under pressures typically used in conventional CVD. Preferably, a pressure of 0.001 to 100 Torr is employed. The process of the present invention may be performed at a temperature typically used in conventional CVD. Preferably, a temperature of from 500 to 1100° C. is employed.

The process of the present invention may be performed with a down stream plasma source, thereby enabling the nanowalls to grow taller in the growth direction.

The two-dimensional, nano-sized structures may be crystalline, such as graphene sheets, or they may be amorphous. The structures may comprise mixtures of crystalline structures, such as mixtures of diamond and graphene crystals, and they may comprise mixtures of crystalline material and amorphous material.

The nanostructures of the present invention are referred to herein as being “two-dimensional”. The term “two-dimensional” is used herein to indicate that the structure has only two dimensions greater than 100 nm. These synthetic structures in fact have a substantially planar or plate like structure wherein the lateral dimensions are substantially greater than the smallest or thickness dimension. Hence such structures may also be referred to as nanowalls or nanoribbons. The lateral dimensions of the nanostructures are preferably from 30×10⁻⁹ m to 10×10⁻⁶ m, more preferably 0.1 to 5×10⁻⁶ m, whereas the smallest or thickness dimension is preferably from 0.05 to 30×10⁻⁹ m, more preferably 0.05 to 5×10⁻⁹ m.

The target plate may comprise any type of material whose melting point is appropriately higher than the employed temperature and wherein said first surface of said target plate is electrically isolated from the second electrode, for example by insulators such as glass, ceramics, low pressure air or vacuum, etc. The second surface of said target plate may be electrically connected to said second electrode, for example by attaching said plate directly to said electrode. Alternatively, for example when said target plate is a thin metal sheet or foil, said second surface may be separated from the second electrode, for example by insulators such as glass, ceramics, low pressure air or vacuum, etc.

Said second surface of said target plate is preferably in electrical contact with said second electrode. Preferably, the target plate comprises one or more layers of insulating material between said first and second surfaces. A preferred insulating material is sapphire, but other suitable insulators include GaAs, GaSb, GaN, glass, SiO₂, Si₄N₃, Al₂O₃ and MgO.

One or more catalysts may be used to promote or suppress the growth of the nano-sized structures. The catalyst may be a solid, liquid or gas, or a form of electromagnetic radiation, such a light source.

The target plate may comprise one or more catalysts that promote growth of the nanowall structures on said first surface. The target plate may comprise one or more layers of catalyst material disposed between said first and second surfaces. Preferably, a layer of catalyst material provides the first surface of the target plate. It is believed that any catalyst material that is suitable for growing nanotubes of a particular material will also be suitable for use in growing nanowalls of the same particular material. Suitable catalyst materials may be formed from one or more of the following elements: Ni, Co, Fe, Mn, Ga, Sn, In, Au and Pt.

The target plate may comprise one or more layers of a porous material, such as anodised aluminium, porous silicon, porous glass, or any other type of material with mesoscopic hole structures.

Preferably, the means for providing an electric field between the electrodes with a zero (earth) or positive charge on said first electrode and a negative charge on said second electrode is a power supply means such as a direct current power supply means, a pulsed direct current power supply means, or an RF power supply means. Most preferably, a direct current power supply means is employed in the present invention.

Preferably, the first and second electrodes are in a simple parallel plate arrangement, such as a pair of parallel plate electrodes. However, the first electrode may be in a more complicated arrangement so that the size and direction of the electrical field on or surrounding the first surface of the target plate may be varied in direction. The electric field on or surrounding the first surface of the target plate may also be varied through the use of microelectrodes positioned in the target plate. In this embodiment, the microelectrodes are insulated from the first surface of the target plate.

A magnetic field may be employed to control the formation of the nanowalls structures. The magnetic field is preferably traversed to the localized electric field that is established immediately above the first surface of the target plate. In this embodiment, the magnetic field direction and distribution may be adjusted through the use of multiple coils positioned around the growth chamber. A magnetic field may be used in addition to the use of an external electric bias.

When gaseous materials or atomic and ion vapours are used as the source of building material, a micro-fluid field may also be used to form the two-dimensional nanostructures.

The invention will now be further described in its various preferred embodiments and by reference to the drawings, in which:

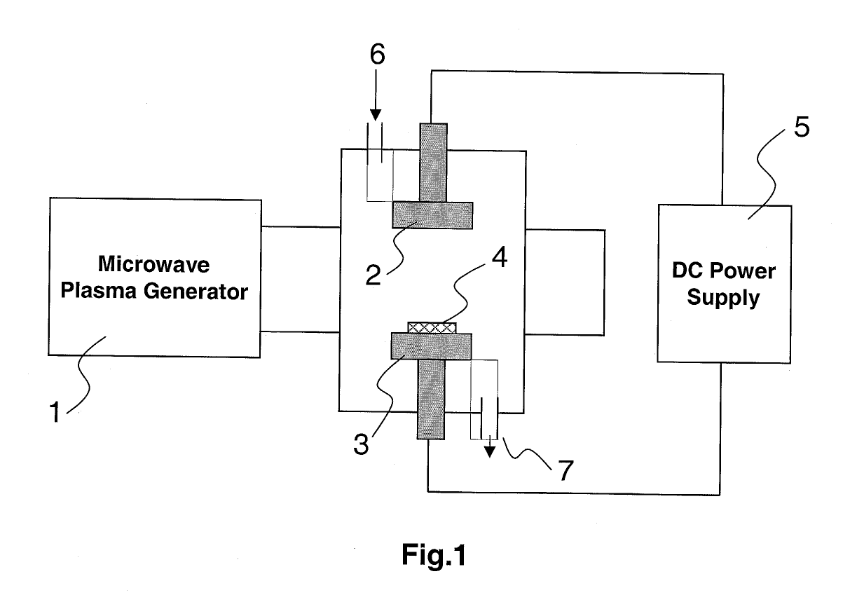

FIG. 1 is a schematic of the CVD apparatus suitable for growing carbon nanotubes and carbon nanowalls.

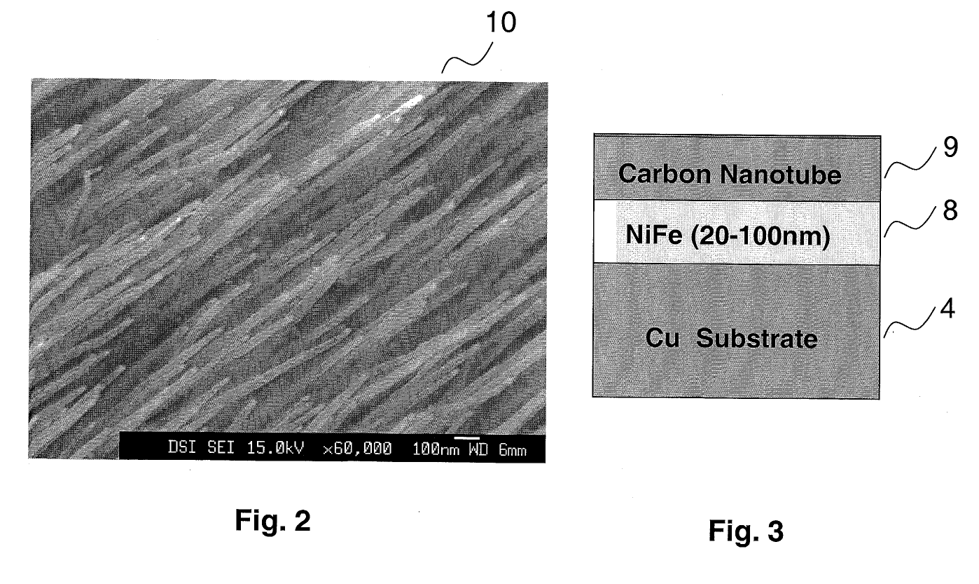

FIG. 2 shows a typical scanning electron microscope image of carbon nanotubes.

FIG. 3 shows a cross-section of a target plate, comprising copper substrate and NiFe catalyst layer, with nanotubes grown thereon.

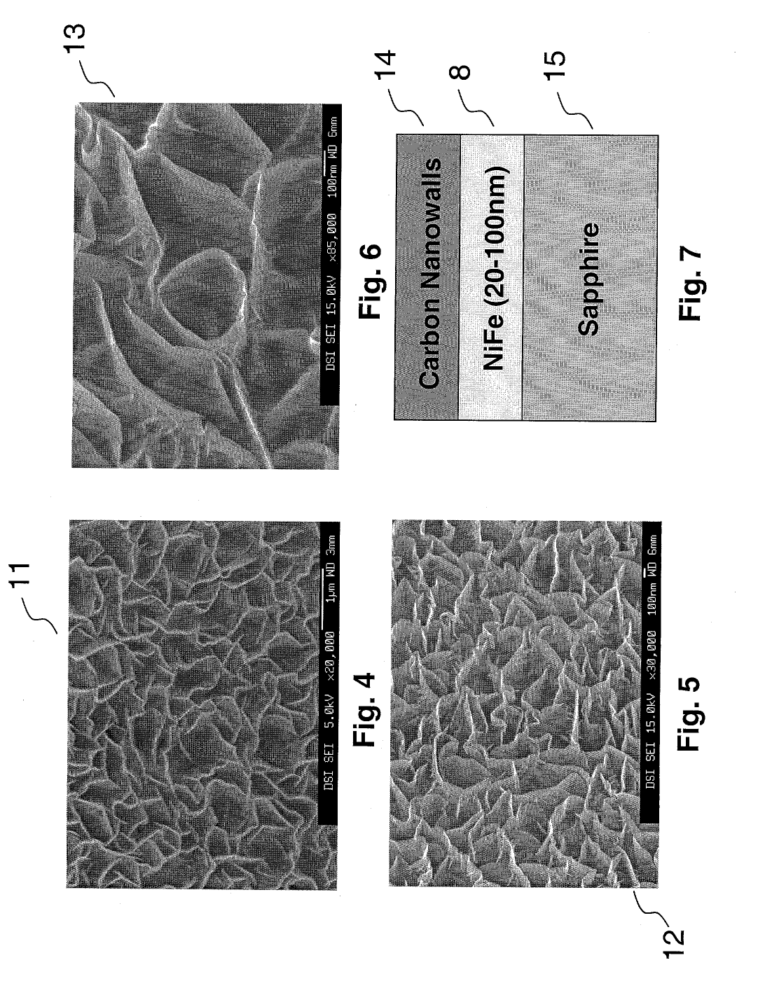

FIG. 4, FIG. 5 and FIG. 6 show typical scanning electron microscope images of carbon nanowalls.

FIG. 7 shows a cross-section of a target plate, comprising a sapphire substrate and NiFe catalyst, with nanowalls grown thereon.

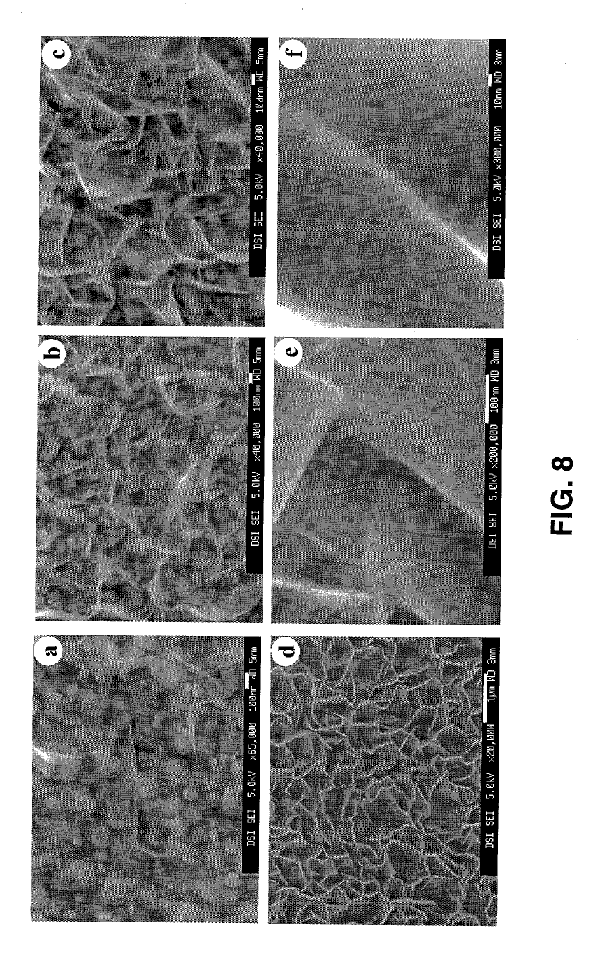

FIG. 8 shows scanning electron microscope images of nanowalls in different growth stages.

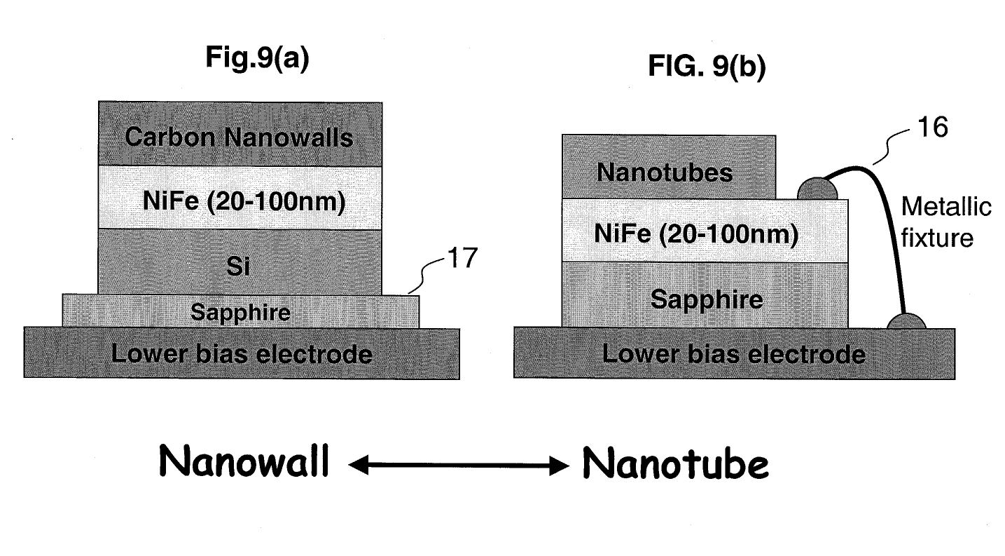

FIG. 9(a) and FIG. 9(b) show how the growth mode can be switched over from the growth of tubes to walls and visa versa through controlling the electrical conduction of the first surface of the target plate.

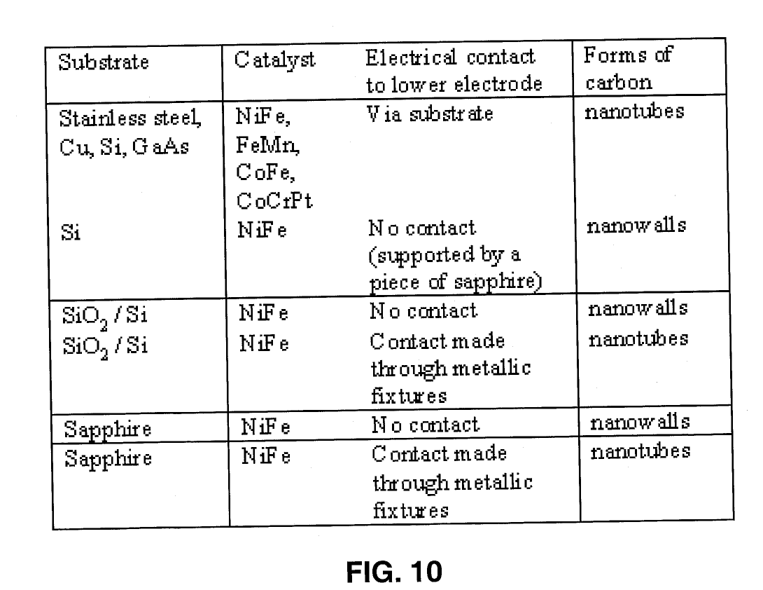

FIG. 10 illustrates the different products obtained by different combination of substrate and electrical conduction to the lower electrodes.

The notations used in the drawings are: 1: microwave generator; 2: first or upper electrode; 3: second or lower electrode; 4: target plate; 5: DC power supply; 6: gas inlet; 7: pumping outlet to pump; 8: catalyst layer forming part of target plate; 9: carbon nanotubes; 10: carbon nanotubes; 11, 12, 13,14: carbon nanowalls; 15: insulating sapphire layer forming part of target plate; 16: conductive metallic fixture; 17: sapphire insulating layer.

Target plates comprising various substrates coated with different types of catalysts have been evaluated. These include Si, stainless steel, Cu, GaAs, and sapphire substrates, coated with NiFe, CoFe, FeMn, and CoCrPt catalysts. All the substrates were conductive except for the sapphire. The catalysts, with a typical thickness ranging from 20 to 100 nm, were deposited in a sputtering system with a base pressure of 3×10⁻⁹ Torr. The growth of nano-sized structures was performed in a microwave plasma enhanced chemical vapour deposition apparatus (FIG. 1), which is equipped with a 500 W microwave source 1 and a traverse rectangular cavity to couple the microwave to a quartz tube for generating the plasma. Inside the quartz tube are two parallel plate electrodes 2 and 3 placed 2 cm away from each other in the longitudinal direction of the tube, and were used to apply a DC bias 5 to promote the growth and alignment of the structures. The gases used were mixtures of CH₄ and H₂, which were fed into the system through the inlet 6. The typical flow rates of H₂ and CH₄ are 40 and 10 sccm, respectively. Before CH₄ was introduced to the quartz tube to commence the growth of nano-sized structures, the target plate was pre-heated to about 650-700° C. in hydrogen plasma without a bias for 8-10 minutes. During both pre-heating and growth, the process pressure was maintained at 1 Torr. A DC bias of −185V was applied to the lower electrode 3 on which the target plate 4 was mounted, while the top electrode 2 was grounded. The growth on all conductive substrates produced well-aligned carbon nanotubes with diameters ranging from 10 nm to 30 nm. As one example, FIG. 2 shows the scanning electron microscopy (SEM) images 10 of typical nanotubes 9 grown on target plate 4 made from a NiFe (40 nm) catalyst layer 8/Cu substrate. In this specific sample, the nanotube diameter is about 30 nm. Under almost identical conditions, however, the nanostructures 14 grown on a target plate made from a NiFe (40 nm) catalyst layer 8/sapphire substrate 15, as illustrated in FIG. 7, showed very little if any resemblance to the nanotubes grown on other conductive substrates; they are well-aligned carbon sheets with a thickness in range of several nanometers (FIGS. 4, 5 and 6). Hereafter we refer them to as carbon nanowalls. FIGS. 4, 5 and 6 show some typical SEM images of the carbon nanowalls grown on a target plate comprising a NiFe (40 nm) (8) coated sapphire substrates 15. The distribution of the nanowalls is remarkably uniform over the whole surface area that is typically 1 cm×1 cm. Occasionally, we could also see some isolated tubular structures like the one shown in FIG. 6. As can be seen from FIGS. 5 and 6, carbon whiskers may be formed on part of the nanowall surfaces.

To have an idea on how these structures were formed initially, SEM images have been taken for films at different growth stages and at different magnifications—FIG 8(a) to (f) ((a) to (c) initial to intermediate stages; (d) after a growth of 5 minutes; (e) a close-up view of a few nanowalls; (f) a close-up view of a single nanowalls. N.B. in this example, the tops of the nanowalls show a folded round shape instead of a single graphene layer. Scale bars: 100 nm in (a)-(c), 1 μm in (d), and 10 nm in (f)). In order to eliminate the influences of the starting materials, the SEM images were taken from the same sample but at different locations (different stages of growth were achieved by placing the substrate at a non-optimum location on the lower electrode). The target plate comprised a 20 nm-thick Ni₈₀Fe₂₀ coated sapphire substrate that was first heated in pure hydrogen plasma for about 8 minutes before the introduction of methane for growing the carbon films. As shown in FIG. 8(a), the catalyst islands can be seen clearly at the initial stage of the growth. Carbon ribbons started to grow across some of the islands that eventually developed into wall-like structures. The nanowalls may grow to meet with one another. In this particular sample, the top edges of the nanowalls appear to be either folded double layers or unfolded single layers, as shown in FIG. 8(e) and FIG. 8(f), respectively. This suggests that some of the nanowalls are hollow shells with nanometer scale spacing. Raman spectra of typical nanowall samples were found to have four peaks with frequencies (full widths at half maximum): 220 (70), 1335 (32), 1584 (16), 1617 (10) cm. The last two peaks with comparable intensities might originate from the nanowalls, while the peak at 1335 cm-1 is related to the diamond phase of carbon formed in between or under the nanowalls. The peak at 220 cm⁻¹ might have something to do with the curvature of carbon sheets at the edges or due to the hollow shells, though the real mechanism is not clear at the moment.

A question as to what could be the possible reasons for the formation of the nanowalls naturally arose after the nanowalls were found on sapphire substrates but not on other types of substrates. It was understood at the beginning that the differences in the surface morphology after the pre-heating were unlikely to be the main reason because all the surfaces after pre-heating showed almost same types of morphologies similar to those shown in FIG. 8(a). Excluding the morphology factor, the next “suspect” naturally went to the electrical conductivity of the substrate because nanowalls were first found growing on sapphire based target plates, which are insulators. In order to confirm this, we first used a piece of sapphire 17 to isolate the electrical conduction from the NiFe-coated Si substrate to the lower electrode (FIG.9(a)), as a result what we obtained were nanowalls instead of nanotubes. Secondly, a new lower electrode was designed to have a metallic fixture 16 so that the top surface of the target plate was electrically connected to the bottom electrode even when sapphire substrate was used (FIG. 9(b)). Then it turned out that the carbons grown on sapphire substrates became nanotubes instead of nanowalls. Similar types of experiments have been done for other types of substrates and electrical connections. The results are summarized in FIG. 10. This series of experiments demonstrated clearly that nanotubes grow when there is an electrical conduction from the catalyst to the electrode, while nanowalls form when the electric conduction is substantially cut off.

Although the mechanism responsible for the growth of different type of carbons is not well understood at the moment, it is postulated that electrical field has played an important role. It has been reported that electric field was closely related to the orientation or alignment of nanotubes in MPECVD. In our case, when the target plate was conductive the electric field was vertical to the substrate due to the DC bias. When the target plate was changed to an insulator, the vertical field should not change so much because the plate is just a dielectric and it only occupied one tenth of the total area of the lower electrode. But one thing might have changed was that the catalyst islands might have been charged up due to the cut off of electrical conduction between the substrate surface and the lower electrode. It is very likely that the charge distributions were non-uniform due to the non-uniformity of the island distribution after the pre-heating. This in turn caused fluctuations of the electrical potential on the sample surface. As a result, a strong traverse electric field was built up across the neighbouring islands. For instance, a voltage difference of 0.1V across two islands with a 0.1 μm spacing would generate an electric field with a strength of 10 kV/cm. This is much stronger than the vertical component of the field, about 90 V/cm in our case. Therefore, it is most likely that the relative strength of the vertical and traverse fields has played a dominant role in determining the form of the carbon that has been grown. Even when it was on an insulating substrate, the surface charges were still movable via plasma or the bi-continuous catalyst. Therefore, the electrical contact to the electrical contact to the substrate surface reduced both the non-uniformity of charge distribution and the total amount of charges, leading to a reduction of the traverse component of the electrical field. This eventually led to the growth of nanotubes.

The present invention can provide novel two-dimensional nanostructures and a method for the preparation of two-dimensional nanostructures.

1. A method for the preparation of a two-dimensional, nano-sized structure by a chemical vapour deposition (CVD) process, the process comprising directing a stream of building material on to a first surface of a target plate for an appropriate period of time to enable a nano-sized structure of said building material to develop on said surface; wherein said target plate comprises said first surface and a second surface on the opposite side of said target plate; characterized in that said first surface of said target plate is electrically insulated from said second surface of said target plate.

2. A method for the preparation of a two-dimensional, nano-sized structure by a chemical vapour deposition (CVD) process as claimed in claim 1, the process comprising directing a stream of building material on to a first surface of a target plate for an appropriate period of time to enable a nano-sized structure of said building material to develop on said surface; wherein said target plate comprises said first surface and a second surface on the opposite side of said target plate; wherein said target plate is located between a first electrode and a second electrode of a pair electrodes with said first surface facing but separated from said first electrode, wherein said pair of electrodes are connected to a means that provides an electric field between said electrodes with a zero (earth) or positive charge on said first electrode and a negative charge on said second electrode, characterized in that said first surface of said target plate is electrically insulated from said second electrode.

3. A method as claimed in claim 1, wherein the two-dimensional nano-sized structure is prepared by a microwave plasma enhanced chemical vapour deposition (MPECVD) process, wherein a stream of plasmatized building material is directed on to said first surface.

4. A method as claimed in claim 1, wherein the two-dimensional, nano-sized structure is prepared by thermal CVD.

5. A method as claimed in claim 1, wherein the building material is selected from carbon, boron nitride, SiC, MoS₃, MoSe₂, GaN, ZnO, TiO₂ and mixtures thereof.

6. A method as claimed in claim 4, wherein the building material is carbon.

7. A two-dimensional nano-sized structure that is other than a non-planar graphene sheet.

8. A two-dimensional nano-sized structure obtainable by the process claimed in claim 1.

9. A two-dimensional nano-sized structure obtained by the process claimed in claim 1.

10. A two-dimensional nano-sized structure obtainable by the process claimed in claim 2.

11. A two-dimensional nano-sized structure obtained by the process claimed in claim 2.

12. Chemical vapour deposition apparatus, suitable for the preparation of two-dimensional nano-sized structures, comprising a) a growth chamber comprising a target plate having a first surface suitable for receiving a stream of building material and a second surface on the opposite side of said target plate; and b) means for establishing an electric field on or immediately above said first surface of said target plate; characterized in that said first surface of said target plate is electrically insulated from said second electrode.

13. Chemical vapour deposition apparatus, as claimed in claim 12, comprising a) a growth chamber comprising a target plate having a first surface suitable for receiving a stream of building material and a second surface on the opposite side of said target plate; wherein said target plate is located between a first electrode and a second electrode of a pair electrodes with said first surface facing but separated from said first electrode and said second surface in electrical contact with said second electrode, and b) means for providing an electric field between said electrodes with a zero (earth) or positive charge on said first electrode and a negative charge on said second electrode; characterized in that said first surface of said target plate is electrically insulated from said second electrode.

14. Apparatus as claimed in claim 13, wherein the means for providing an electric field between the electrodes with a zero (earth) or positive charge on said first electrode and a negative charge on said second electrode is a power supply means selected from a direct current power supply means, a pulsed direct current power supply means, and an RF power supply means.

15. Apparatus as claimed in claim 14, wherein the power supply means is a direct current power supply means.

16. Apparatus as claimed in claim 12, wherein the apparatus is microwave plasma enhanced chemical vapour deposition (MPECVD) apparatus.

17. Apparatus as claimed in claim 12, wherein the apparatus is thermal CVD apparatus.

18. Apparatus as claimed in claim 13, wherein the first and second electrodes are a pair of parallel plate electrodes located within the growth chamber.

19. Apparatus as claimed in claim 13, wherein the first electrode is comprised of a plurality of electrodes of the same electrical charge located around the growth chamber to provide a means for controlling the size and direction of the electric field on or surrounding the first surface of the target plate.

20. Apparatus as claimed in claim 13, wherein the target plate comprises one or more microelectrodes to provide a means for controlling the direction of the electric field on or surrounding the first surface of the target plate.

21. Apparatus as claimed in claim 12, wherein one or more electric coils are positioned close to the growth chamber to provide a means for controlling the direction of the electric field on or immediately above the first surface of the target plate.
